(19) United States
(12) Patent Application Publication
(10) Pub. No.: US 2007/0098879 A1
(43) Pub. Date: May 3, 2007

(54) METHOD OF MANUFACTURING LIGHT-EMITTING ELEMENT, LIGHT-EMITTING ELEMENT, LIGHT-EMITTING DEVICE AND ELECTRONIC APPARATUS

(75) Inventor: Rie MAKIURA, Suwa-shi, Nagano-ken (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/470,498

(22) Filed: Sep. 6, 2006

(30) Foreign Application Priority Data
Oct. 27, 2005 (JP) 2005-313520

(51) Int. Cl. B05D 5/12; C08J 7/18

(52) U.S. Cl. 427/66; 427/553

(57) ABSTRACT

The method of manufacturing a light-emitting element includes: a) forming a coating film made mostly of a polysiloxane derivative, the process a) including applying a monomer corresponding to the desired polysiloxane derivative on a surface of an anode and polymerizing the monomer by plasma polymerization,; b) forming an anode buffer layer, the process b) including irradiating ultraviolet light onto the coating film to change the polysiloxane derivative in the coating film into silicon dioxide (SiO₂); c) forming a semiconductor layer having at least a light-emitting layer on the anode buffer layer ;and d) forming a cathode on a side opposite to the anode of the semiconductor layer.

### BACKGROUND

1. Technical Field

The present invention relates to a method of manufacturing a light-emitting element, a light-emitting element, a light-emitting device and an electronic apparatus.

2. Related Art

An organic electroluminescent element (hereinafter referred to as an “organic EL element”) has been available that has a structure in which at least one light-emitting organic layer (organic electroluminescent layer) is disposed between an anode and a cathode. Compared with an inorganic EL element, such an organic EL element can significantly reduce the amount of voltage to be applied, and multicolor-light emitting organic EL elements can be manufactured (e.g., See patent and nonpatent literature below).

In order to produce an organic EL element with higher performance capabilities, along with the development and improvement of materials, various element structures are presently being proposed and active research is underway.

Additionally, organic EL elements have been developed that can emit various colors of light and can exhibit a high level of luminance, high efficiency and a long lifetime. Regarding those products, a wide variety of practical applications including display pixels and light sources has been considered.

Then, various researches are being conducted to put them to practical uses in an effort to achieve more light-emitting efficiency and durability (lifetime).

JP-A-10-153967 is a first example of related art.

JP-A-10-12377 is a second example of related art.

JP-A-11-40358 is a third example of related art.

Applied Physics Lett., 51(12), 21 Sep. 1987, p. 913., is a first nonpatent example of related art.

Applied Physics Lett., 71(1), 7 Jul. 1997, p. 34., is a second nonpatent example of related art.

Nature., 357, 1992, p. 477., is a third nonpatent example of related art.

### SUMMARY

An advantage of the present invention is to provide a method of manufacturing a light-emitting element with excellent light-emitting efficiency and durability (lifetime), a light-emitting element manufactured by the method, a highly reliable light-emitting device including the light-emitting element and an electronic apparatus including the light-emitting device.

In order to achieve the above advantage, a method of manufacturing a light-emitting element according to an aspect of the invention includes a first process for forming a coating film made mostly of a polysiloxane derivative, the first process including supplying a monomer corresponding to the desired polysiloxane derivative on a surface of an anode and polymerizing the monomer by plasma polymerization, a second process for forming an anode buffer layer, the second process including irradiating ultraviolet light onto the coating film to change the polysiloxane derivative in the coating film into silicon dioxide (SiO₂), a third process for forming a semiconductor layer having at least a light-emitting layer on the anode buffer layer and a fourth process for forming a cathode on a side opposite to the anode of the semiconductor layer.

According to the method of the above aspect, a light-emitting element can be manufactured that is excellent in light-emitting efficiency and durability (lifetime).

In the method according to the above aspect, it is preferable that the polysiloxane derivative include a substituent from at least one of an alkyl group with carbon numbers of 1 to 8, an alkoxyl group with carbon numbers of 1 to 8 and a halogen group.

The polysiloxane derivative with such a substituent has particularly high lyophobic properties. As a result, the polysiloxane derivative can prevent alteration and deterioration due to moisture absorption during the processes.

In the method according to the above aspect, it is preferable that an energy of the irradiated ultraviolet light be greater than a binding energy between silicon and the substituent, and smaller than a silicon-oxygen (Si—O) binding energy.

In this manner, without substantially breaking the Si—O binding, the binding of silicon and the substituent can selectively be broken. As a result, the polysiloxane derivative can be changed into SiO₂ more effectively, whereby the anode buffer layer can be formed.

In the method according to the above aspect, it is preferable that the ultraviolet light be irradiated in an atmosphere containing no oxygen.

In this manner, since ultraviolet-light absorption and ozone formation due to oxygen can be prevented, the polysiloxane derivative can effectively be changed into SiO₂. Consequently, SiO₂ generated by the ultraviolet-light irradiation can reliably be protected from alteration and deterioration due to influence of water vapor.

In the method according to the above aspect, it is preferable that the third process be started before alteration due to moisture absorption or attachment of impurities occurs on the anode buffer layer after the second process.

This can reduce a time in which moisture absorption and the attachment of impurities can occur on the SiO₂ surface. Consequently, the method can prevent associated alteration and deterioration of the anode buffer layer and poor contact thereof with a semiconductor layer.

In the method according to the above aspect, it is preferable that the third process be started in an air atmosphere within 5 minutes after the second process.

Such a short-time exposure can more reliably prevent the anode buffer layer from absorbing moisture even in the air atmosphere, and thus can prevent the alteration and deterioration thereof.

In the method according to the above aspect, it is preferable that the anode buffer layer be formed so as to have a mean thickness of equal to or less than 10 nm.

In this manner, the anode buffer layer can more reliably perform a function of injecting a positive hole into a positive-hole transporting layer from the anode, while preventing a significant increase in a drive voltage of the organic EL element.

A light-emitting element according to the aspect of the invention is manufactured by the method according to the aspect thereof.

The method can provide a light-emitting element having excellent light-emitting efficiency and durability (lifetime).

A light-emitting device according to the aspect of the invention includes the light-emitting element mentioned above.

Thereby, a highly reliable light-emitting device can be manufactured.

An electronic apparatus according to the aspect of the invention includes the light-emitting device mentioned above.

Thereby, a highly reliable electronic apparatus can be manufactured.

### BRIEF DESCRIPTION OF THE DRAWINGS

The invention will be described with reference to the accompanying drawings, wherein like numbers reference like elements.

FIG. 1 is a longitudinal cross-sectional view showing an active matrix display applied as a light-emitting device according to a first embodiment of the invention.

FIGS. 2A to 2C are explanatory views illustrating a method of manufacturing the active matrix display shown in FIG. 1.

FIGS. 3A to 3C are explanatory views illustrating the method of manufacturing the active matrix display shown in FIG. 1.

FIG. 4A is an explanatory view illustrating the method of manufacturing the active matrix display shown in FIG. 1.

FIG. 5 is a schematic diagram showing a structure of a plasma polymerizing apparatus.

FIG. 6 is a longitudinal cross-sectional view showing an active matrix display applied as a light-emitting device according to a second embodiment of the invention.

FIG. 7 is a longitudinal cross-sectional view showing an active matrix display applied as a light-emitting device according to a third embodiment of the invention.

FIG. 8 is a perspective view showing a structure of a mobile (or notebook) personal computer applied as an example of an electronic apparatus according to the embodiments of the invention.

FIG. 9 is a perspective view showing a structure of a mobile phone (including PHS) as applied as another example of the electronic apparatus according to the embodiments of the invention.

FIG. 10 is a perspective view showing a structure of a digital still camera applied as another example of the electronic apparatus according to the embodiments of the invention.

### DESCRIPTION OF EXEMPLARY EMBODIMENTS

The invention will be described in detail hereinafter by way of suitable embodiments.

### First Embodiment

First, descriptions will be given of an active matrix display applied as a light-emitting device according to a first embodiment of the invention, an organic EL element applied as a light-emitting element according to the first embodiment thereof, which is included in the active matrix display, and a method of manufacturing the organic EL element.

Active Matrix Display

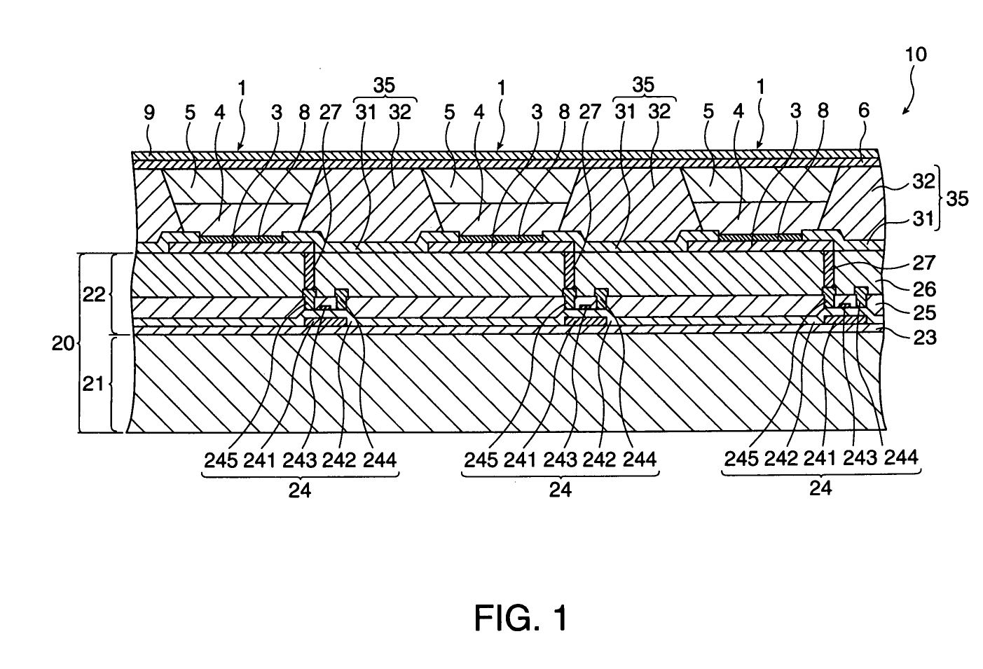

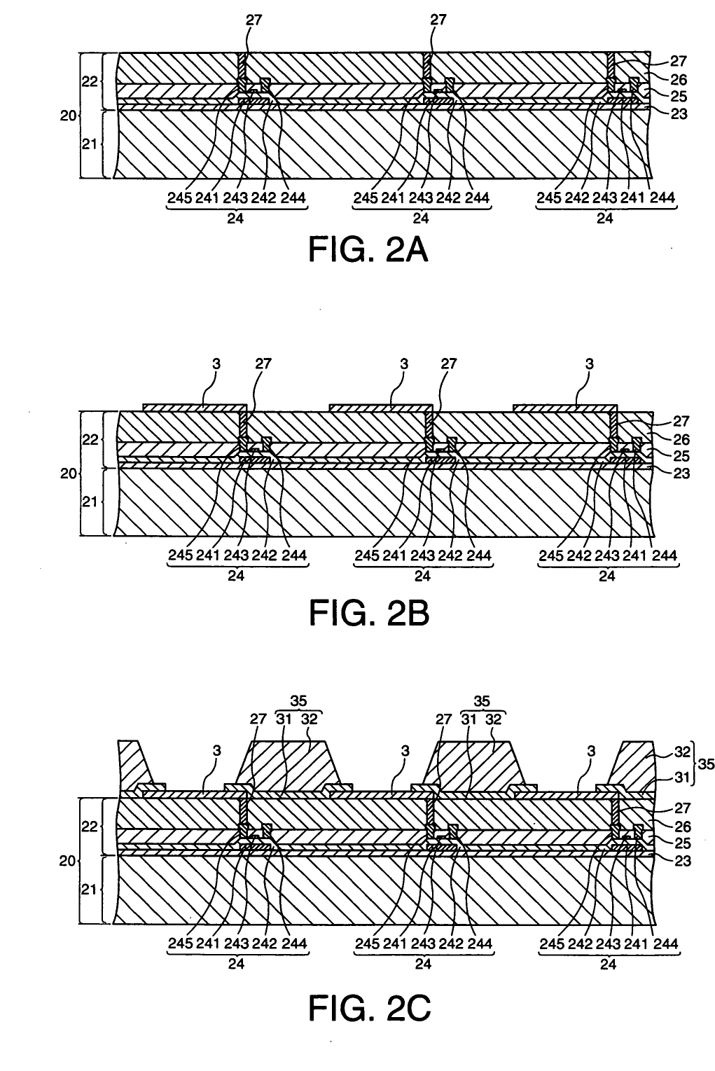

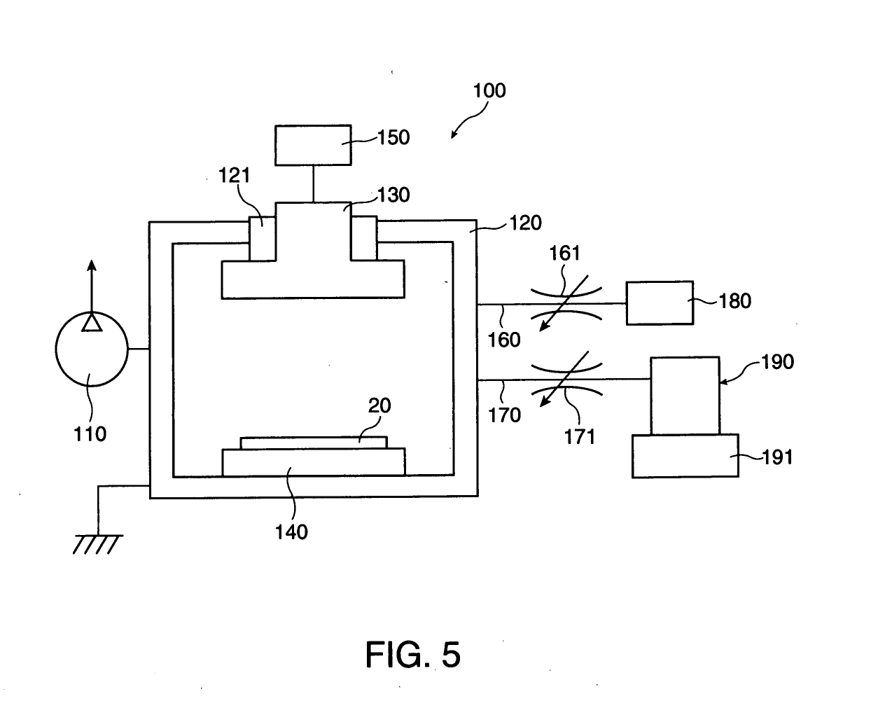

FIG. 1 is a longitudinal cross-sectional view showing the active matrix display as the light-emitting apparatus according to the first embodiment. FIGS. 2A to 4A are explanatory views illustrating the method of manufacturing the active matrix display shown in FIG. 1. FIG. 5 is a schematic diagram showing a structure of a plasma polymerizing apparatus. Additionally, in the description below, upper and lower sides in each of FIGS. 1 to 5 will be referred to as “upper” and “lower”, respectively.

An active matrix display (hereinafter referred to as a “display”) 10 shown in FIG. 1 has a TFT circuit substrate (opposing substrate) 20, an organic EL element (the light-emitting element according to the embodiment) 1 disposed on the substrate 20 and an upper substrate 9 opposing the TFT circuit substrate 20.

The TFT circuit substrate 20 has a substrate 21 and a circuit section 22 formed on the substrate 21.

The substrate 21 functions as a supporting body for each section constituting the display 10. The upper substrate 9, for example, functions as a protective film or the like for protecting the organic EL element 1.

Additionally, the display 10 according to the first embodiment has a structure in which light is taken out from the substrate 21 side (bottom emission type structure). Thus, the substrate 21 is to be substantially transparent (water-clear, colored transparent or half-transparent), although transparency is not particularly required for the upper substrate 9.

As the substrate 21, among various kinds of glass substrates and resin substrates, it is suitable to use a substrate having a relatively high hardness.

On the other hand, as for the upper substrate 9, a transparent substrate will be selected from various kinds of glass substrates and those transparent among various kinds of rein substrates. For example, the substrate may be made mostly of glass such as silica glass or soda glass, or a resin such as polyethylene terephthalate, polyethylene naphthalate, polypropylene, cycloolefin polymer, polyamide, polyethersulfone, polymethyl methacrylate, polycarbonate, polyarylate or the like.

A mean thickness of the substrate 21 is not particularly limited, but preferably it ranges from approximately 1 to 30 mm, and more preferably from approximately 5 to 20 mm. Meanwhile, a mean thickness of the upper substrate 9 is similarly not limited to a particular range, but preferably, it ranges from approximately 0.1 to 3.0 mm, and more preferably from approximately 0.1 to 10 mm.

The circuit section 22 has a base protective layer 23 formed on the substrate 21, a driving TFT (switching device) 24 formed on the base protective layer 23, a first interlayer insulating layer 25 and a second interlayer insulating layer 26.

The driving TFT 24 has a semiconductor layer 241, a gate insulating layer 242 formed on the semiconductor layer 241, a gate electrode 243 formed on the gate insulating layer 242, a source electrode 244 and a drain electrode 245.

Each organic EL element 1 corresponding to each driving TFT 24 is disposed on the circuit section 22. Additionally, the mutually adjacent organic EL elements are partitioned by a bank 35 composed of first and second banks 31 and 32.

In the first embodiment, an anode 3 of each organic EL element 1 forms a pixel electrode and is electrically connected to the drain electrode 245 of each driving TFT 24 by a wire 27. In addition, a positive-hole transporting layer 4 and a light-emitting layer 5 are formed individually for each organic EL element 1. The anode 3 is a common electrode.

The display 10 may be a monochromatic display or a full-color display produced by selecting a light-emitting material for each organic EL element 1.

A detail of the organic EL element 1 will be explained below.

As shown in FIG. 1, the organic EL element 1 has the anode 3, a cathode 6, and between them, an organic semiconductor layer (multilayer laminated structure) formed by laminating the positive-hole transporting layer 4 and then the light-emitting layer 5 in the sequential order from the anode 3 side. Furthermore, an anode buffer layer 8 is disposed between the anode 3 and the positive-hole transporting layer 4.

The anode 3 is an electrode for injecting a positive hole into the positive-hole transporting layer 4 via the anode buffer layer 8 to be described later.

As a material forming the anode 3 (anode material), it is preferable to use a material having a large work function, excellent conductivity, and translucency.

Examples of such an anode material may include oxide compounds such as ITO (a compound of indium oxide and zinc oxide), SnO₂, Sb-containing SnO₂ and Al-containing ZnO, Au, Pt, Ag, Cu, alloys thereof, etc. At least one of these materials may be used for the anode 3.

Although a mean thickness of the anode 3 is not particularly limited, it preferably ranges from approximately 10 to 200 nm, and more preferably from approximately 50 to 150 nm. If the thickness thereof is extremely thin, the anode 3 cannot function sufficiently. Meanwhile, if it is excessively thick, depending on the kind of the anode material or the like, optical transparency significantly decreases. Consequently, if the organic EL element 1 has a top emission type structure, it cannot be applied to practical use.

As the anode material, for example, a conductive resin such as polythiophene, polypyrrole or the like may be used.

On the other hand, the cathode 6 is an electrode for injecting an electron into the light-emitting layer 5 to be described later. A material forming the cathode 6 preferably has a small work function.

As examples of the material of the cathode 6, there may be mentioned Li, Mg, Ca, Sr, La, Ce, Er, Eu, Sc, Y, Yb, Ag, Cu, Al, Cs, Rb or alloys of them. Among them, a kind of material or a combination of two or more kinds of materials may be used (e.g., a multilayer laminated structure).

In particular, when using an alloy as the material of the cathode 6, it is preferable to use an alloy containing a stable metallic element such as Ag, Al or Cu, specifically, an alloy such as MgAg, AlLi or CuLi. Use of any of the alloys as the material of the cathode 6 can increase efficiency and stability of electron injection from the cathode 6.

Although a mean thickness of the cathode 6 is not particularly limited, preferably, the thickness ranges from approximately 100 to 10000 nm, and more preferably from approximately 200 to 500 nm.

Additionally, since the light-emitting element 1 according to the embodiment has a bottom emission type structure, optical transparency is not particularly required for the cathode 6.

The positive-hole transporting layer 4 has a function of transporting a positive hole injected from the anode 3 to the light-emitting layer 5.

As a material forming the positive-hole transporting layer 4 (positive-hole transportation material), for example, there may be mentioned polyallylamine, fluorene-allylamine copolymer, fluorene-bithiophene copolymer, poly(N-vinylcarbazole), polyvinyl pyrene, polyvinyl anthracene, polythiophene, polyalkylthiophene, polyhexylthiophene, poly(p-phenylenevinylene), polythienylenevinylene, pyrene-formaldehyde resin, ethyl carbazole-formaldehyde resin or derivatives thereof. Among them, a kind of compound or a combination of two or more kinds thereof may be used.

Although a mean thickness of the positive-hole transporting 4 is not particularly limited, preferably, it ranges from approximately 10 to 150 nm, and more preferably from approximately 50 to 100 nm.

The light-emitting layer (organic light-emitting layer) 5 is disposed on the positive-hole transporting layer 4. An electron from the cathode 6 to be described later and a positive hole from the positive-hole transporting layer 4 are each supplied (injected) into the light-emitting layer 5. This results in recombination of the positive hole and the electron in the light-emitting layer 5. Then, energy discharged by the recombination generates exciton, and upon transition of the exciton back to the ground state, energy (fluorescence or phosphorescence) is discharged (light emission).

As a material for the light-emitting layer 5, there may be mentioned thiadiazole compounds such as benzothiadiazole, benzene compounds such as 1,3,5-tris[(3-phenyl-6-trisfluoromethyl)quinoxaline-2-yl]benzene (TPQ 1) and 1,3,5-tris [{3-(4-t-butylphenyl)-6-trifluoromethyl}-quinoxaline-2-yl]benzene (TRQ 2), metal or metal-free phthalocyanine compounds such as phthalocyanine, copper phthalocyanine (CuPc) and iron phthalocyanine, low molecular compounds such as tris(8-hydroxyquinolate)-aluminum (Alq₃) and fac tris(2-phenylpyridine)iridium (Ir (ppy)₃) and high molecular compounds such as fluorene-based compounds including dioctylfluorene, oxadiazole-based compounds, triazole-based compounds and carbazole-based compounds. Among them, a kind of compound or a combination of two or more kinds of compounds may be used.

In addition, between the cathode 6 and the light-emitting layer 5, for example, an electron transporting layer may be disposed that has a function of transporting an electron injected from the cathode 6 to the light-emitting layer 5. Furthermore, between the electron transporting layer and the cathode 6, an electron injecting layer may be disposed to improve efficiency in injecting the electron into the electron transporting layer from the cathode 6.

As a material used for forming the electron transporting layer (electron transportation material), there may be mentioned benzene compounds (starburst compounds) such as 1,3,5-tris[(3-phenyl-6-trisfluoromethyl)quinoxaline-2-yl]benzene (TPQ 1) and 1,3,5-tris[{3-(4-tert-butylphenyl)-6-trifluoromethyl}-quinoxaline-2-yl]benzene (TPQ 2), naphthalene compounds such as naphthalene, phenanthrene compounds such as phenanthrene, chrysene compounds such as chrysene, perylene compounds such as perylene, anthracene compounds such as anthracene, pyrene compounds such as pyrene, acridine compounds such as acridine, stilbene compounds such as stilbene, thiophene compounds such as BBOT, butadiene compounds such as butadiene, coumarin compounds such as coumarin, quinoline compounds such as quinoline, bistyryl compounds such as bistyryl, pyrazine compounds such as pyrazine and distyryl pyrazine, quinoxaline compounds such as quinoxaline, benzoquinon compounds such as benzoquinon and 2,5-diphenyl-p-benzoquinon, naphthoquinone compounds such as naphthoquinone, anthraquinone compounds such as anthraquinon, oxadiazole compounds such as oxadiazole, 2-(4-biphenyl)-5-(4-tert-butylphenyl)-1,3,4-oxadiazole (PBD), BMD, BND, BDD and BAPD, triazole compounds such as triazole, 3,4,5-triphenyl-1,2,4-triazole, oxazole compounds, anthrone compounds such as anthrone, fluorenone compounds such as fluorenone and 1,3,8-trinitro-fluorenone (TNF), diphenoquinone compounds such as diphenoquinone and MBDQ, stilbenequinone compounds such as stilbenequinone and MBSQ, anthraquinodimethane compounds, thiopyran dioxide compounds, fluorenylidenemethane compounds, diphenyldicyanoethylene-based compounds, metallic or non-metallic phthalocyanine compounds such as phthalocyanine, copper phthalocyanine, and iron phthalocyanine, and various kinds of metallic complexes such as 8-hydroxyquinoline aluminum (Alq.sub.3) and complexes having benzooxazole or benzothiazole as a ligand.

Other than those, as the material of the electron transporting layer (electron transportation material), for example, it is also possible to use a high-molecular material such as an oxadiazole-based high molecular compound (polyoxadiazole), a triazole-based high molecular compound (polytriazole) or the like.

Although a mean thickness of the electron transporting layer is not particularly limited, the preferable thickness thereof ranges from approximately 1 to 100 nm, and a more preferable thickness ranges from approximately 20 to 50 nm.

Additionally, as a material for forming the electron injecting layer (electron injection material), there may be mentioned 8-hydroxyquinoline, oxadiazole, any of the derivatives thereof (e.g. an 8-hydroxyquinoline-containing metallic chelate oxinoid compound) or the like. Among them, a kind of compound or a combination of two or more kinds of compounds may be used (for example, as a multilayer laminated structure or the like). Alternatively, any of other various kinds of inorganic insulating materials, inorganic semiconductor materials, etc., may be used as the electron injection material.

Formation of the electron injecting layer made mostly of an inorganic insulating material or an inorganic semiconductor material can efficiently prevent current leakage, resulting in improvement in the electron injection efficiency and durability thereof.

As such an inorganic insulating material, for example, there may be used any of alkali metal chalcogenides (e.g. oxide compounds, sulfide compounds, selenium compounds and tellurium compounds), alkaline-earth metal chalcogenides, alkali metal halides, alkaline-earth metal halides and the like. Among them, a kind of compound or a combination of two or more kinds thereof may be used. Formation of the electron injecting layer by using any of them as a main material can further improve electron-injection efficiency thereof.

Examples of the alkali metal chalcogenides include Li₂O, LiO, Na₂S, Na₂Se, NaO, etc.

Examples of the alkaline-earth metal chalcogenides include CaO, BaO, SrO BeO, BaS, MgO, CaSe, etc.

Examples of the alkali metal halides include CsF, LiF, NaF, KF, LiCl, KCl, NaCl, etc.

Examples of the alkaline-earth metal halides include CaF₂, BaF₂, SrF₂, MgF₂, BeF₂, etc.

Additionally, examples of the inorganic semiconductor materials include oxides, nitrides and oxynitrides containing at least one element of Ba, Ca, Sr, Nb, Al, Ga, In, Li, Na, Cd, Mg, Si, Ta, Sb and Zn. Among them, a kind of compound or a combination of two or more kinds thereof may be used.

Furthermore, when the electron injecting layer is formed with such an inorganic material, it is preferable to use a microcrystal or amorphous inorganic material. This allows the electron injecting layer to be more homogenous, thereby reducing pixel defects such as the occurrence of dark spots.

Here, as shown in FIG. 1, the organic EL element according to the embodiment is provided with the anode buffer layer 8 contacting with the anode 3 and the positive-hole transporting layer 4.

The anode buffer layer 8 is disposed between the anode 3 and the positive-hole transporting layer 4. This arrangement can reduce a so-called carrier injection barrier, which is an energy difference between a Fermi level of the anode 3 and a highest occupied molecular orbital (the highest energy molecular orbital of those occupied by electrons: HOMO) level of the positive-hole transporting layer 4. Consequently, the anode buffer layer 8 will have a positive-hole injection function for facilitating transportation of a positive hole from the anode 3 to the positive-hole transporting layer 4.

The anode buffer layer 8 is formed mostly of silicon dioxide (SiO₂). Disposition of the SiO₂ layer between the anode 3 and the positive-hole transporting layer 4 reduces a difference between a work function of the anode 3 and the HOMO level of the positive-hole transporting layer 4 due to effects of band bending and a vacuum level shift. The reduction effect varies with the materials of the anode 3 and the positive-hole transporting layer 4 and the thickness of the anode buffer layer 8. Consequently, the carrier injection barrier between the anode 3 and the positive-hole transporting layer 4 is reduced, which will facilitate the transportation of a positive hole from the anode 3 to the positive-hole transporting layer 4. As a result, the display 10 can have high light-emission efficiency.

In addition, since SiO₂ is substantially transparent, it is applicable even in the structure in which light is taken out through the anode 3 as in the organic EL element 1 according to the embodiment.

Furthermore, a mean thickness of the anode buffer layer 8 is preferably as thin as possible. Specifically, the mean thickness thereof is preferably equal to or less than 10 nm, and more preferably equal to or less than 7 nm. This ensures that a carrier passes through the anode buffer layer 8, resulting in generation of a tunnel current. Consequently, the anode buffer layer 8 can reliably fulfill the role of injecting a positive hole from the anode 3 to the positive-hole transporting layer 4, while preventing a significant increase in a driving voltage of the organic EL element 1.

The display 10 described above will be manufactured by applying a light-emitting element manufacturing method according to the embodiment of the invention, as below:

[1] Initially, the TFT circuit substrate 20 as shown in FIG. 2A is prepared.

[1-A] First, the substrate 21 is prepared, and the base protective layer 23 is formed thereon, for example, by a plasma CVD method or the like using tetraethoxysilane (TEOS), oxygen gas or the like as a raw material gas. The base protective layer 23 is made mostly of a silicon oxide material having a mean thickness ranging from approximately 200 to 500 nm.

[1-B] Next, a driving TFT 24 is formed on the base protective layer 23.

[1-Ba] Initially, in a state in which the substrate 21 has been heated at approximately 350 degrees Centigrade, a semiconductor film is formed on the base protective layer 23, for example, by a plasma CVD method or the like. The semiconductor film is made mostly of amorphous silicon having a mean thickness ranging from approximately 30 to 70 nm.

[1-Bb] Then, the semiconductor film is crystallized by using laser annealing, a solid-phase growth method or the like to change the amorphous silicon into polysilicon.

Here, as for the laser annealing, an excimer laser may be used. In this case, for example, a line beam thereof may have a long-side length of 400 mm and an output power level thereof may be approximately 200 mJ/cm². Additionally, regarding the line beam, scanning is performed with an overlapping ratio equivalent to 90% of a peak laser intensity in a short-side direction thereof in each region.

[1-Bc] Next, the semiconductor film is patterned to be island-shaped. Then, the gate insulating layer 242 is formed, for example, by a plasma CVD method or the like using a tetraethoxysilane (TEOS) gas, an oxygen gas or the like as a raw material gas so as to cover each island-shaped semiconductor layer 241. The gate insulating layer 242 is made mostly of silicon oxide, silicon nitride or the like having a mean thickness ranging from approximately 60 to 150 nm.

[1-Bd] Next, a conductive film is formed on the gate insulating layer 242, for example, by sputtering or the like. The conductive film is made mostly of a metallic material such as aluminum, tantalum, molybdenum, titanium, tungsten or the like. After that, the conductive film is patterned to form the gate electrode 243.

[1-Be] Subsequently, in this situation, a high-dose phosphorus ion implantation is performed to form a source-drain region in a self-aligning manner with respect to the gate electrode 243. Additionally, a part where impurities have not been introduced becomes a channel region.

[1-C] Next, the source electrode 244 and the drain electrode 245 are formed to be electrically connected to the driving TFT 24.

[1-Ca] First, after forming the first interlayer insulating layer 25 so as to cover the gate electrode 243, a contact hole is formed.

[1-Cb] Next, the source electrode 244 and the drain electrode 245 are formed within the contact hole.

[1-D] Then, the wire 27 (relay electrode) is formed to electrically connect the drain electrode 245 and the anode 3.

[1-Da] Initially, after forming the second interlayer insulating layer 26 on the first interlayer insulating layer 25, a contact hole is formed.

[1-Db] Next, the wire 27 is formed within the contact hole. In the manner described above, the TFT circuit substrate 20 can be produced.

[2] Then, the organic EL element 1 is formed on the TFT circuit substrate 20.

[2-A] Initially, as shown in FIG. 2B, the anode (pixel electrode) 3 is formed on the second interlayer insulating layer 26 included in the TFT circuit substrate 20 so as to contact with the wire 27.

The anode 23 may be formed, for example, by a gas-phase process such as sputtering, vacuum deposition, CVD or the like, a liquid-phase process such as spin coating (pyrosol process), casting, microgravure coating, gravure coating, bar coating, roll coating, wire-bar coating, dip coating, spray coating, screen printing, flexoprinting, offset printing or inkjet printing, or the like.

Any of the methods will be selected considering thermal stability of a material forming the anode 3, physical properties of the material such as solubility in a solvent and/or chemical properties thereof.

[2-B] Next, the bank 35 is formed on the second interlayer insulating layer 26 so as to partition each anode 3, as shown in FIG. 2C.

After forming the first bank 31 on the second interlayer insulating film 26, the bank 35 can be formed by forming the second bank 32 on the first bank 31.

The first bank 31 can be formed by pattering, etc., using photolithography, etc., after forming an insulating film so as to cover the anode 3 and the second interlayer insulating film 26. Additionally, the second bank 32 can be formed in a similar manner to the formation of the first bank 31, after forming an insulating film so as to cover the anode 3 and the first bank 31.

Materials for forming the first and second banks 31 and 32 are selected considering thermotolerance, lyophobic properties, ink-solvent resistance, adhesiveness to a base layer, etc.

Specifically, as a material for the first bank 31, for example, there may be used any of organic materials such as acrylic resin and polyimide resin or inorganic materials such as SiO₂. Among them, particularly, when oxide is used as a main material for the anode 3, it is preferable to use SiO₂. This can improve adhesiveness between the anode 3 and the first bank 31.

In addition, as a material for the second bank 32, other than those shown for the first bank 31, for example, there may be used fluorine resin or the like. Use of fluorine resin can improve moisture resistance of the second bank 32.

Furthermore, the shape of an opening of the bank 35 may be, for example, circular, oval, square, polygonal such as hexagonal or the like, and is not limited to any specific shape.

When the bank 35 has a polygonal opening, it is preferable that corners of the polygonal opening be rounded. With this arrangement, when the positive-hole transporting layer 4 and the light-emitting layer 5 are each formed with a liquid material to be described later, the material can reliably be supplied to every corner of a space inside the bank 35.

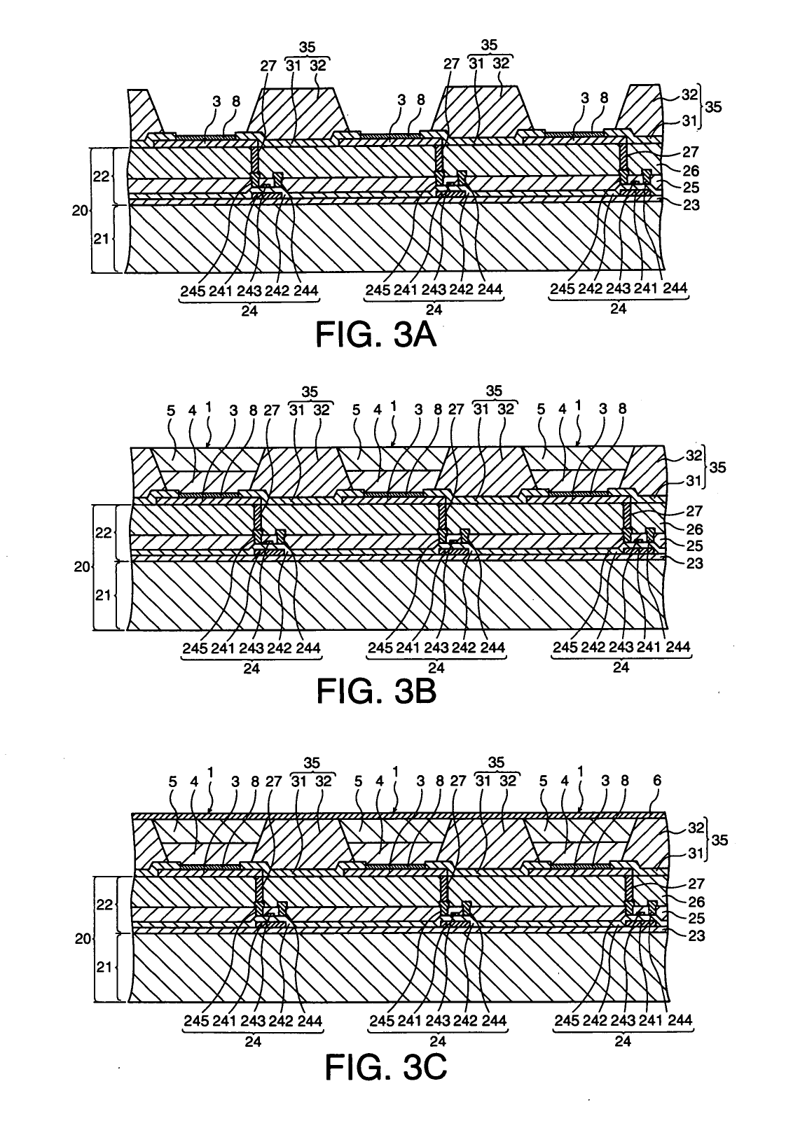

A height of the bank 35 is set appropriately in consideration of a total thickness of the anode 3, the anode buffer layer 8, the positive-hole transporting layer 4 and the light-emitting layer 5, and is not limited to any specific height. However, preferably it ranges from approximately 30 to 500 nm. The range allows the bank 35 to fulfill its role sufficiently.

[2-C] Next, as shown in FIG. 3A, each anode buffer layer 8 is formed on each anode 3.

[2-Ca] First, a coating film made mostly of a polysiloxane derivative is formed on the anode 3 in the inner space of the bank 35 (First Process).

The coating film is, for example, formed by plasma polymerization using a plasma polymerizing apparatus 100 as shown in FIG. 5.

The plasma polymerizing apparatus 100 shown in FIG. 5 has a vacuum chamber 120 which is connected to a vacuum pump 110. An electrode 130 and a stage 140 are disposed within the vacuum chamber 120.

The electrode 130 is disposed at an upper part of the vacuum chamber 120 via an insulating member 121, and connected to a high-frequency electric power supply 150 arranged outside the vacuum chamber 120. The high-frequency electric power supply 150 outputs a high-frequency electric power.

Preferably, an output of the high-frequency electric power (plasma output) ranges from approximately 5 to 500 W, and more preferably from approximately 50 to 200 W.

A frequency of the high-frequency electric power is not particularly limited, and for example, may be set at 13.56 MHz, the usual industrial frequency.

The stage 140 is provided with the TFT circuit substrate 20 (processed substrate) having the first bank 31 thereon. At a lower part in the vacuum chamber 120, the stage 140 is arranged opposite to the electrode 130. Additionally, the stage 140 is provided with a temperature adjustment mechanism for adjusting a temperature of the TFT circuit substrate 20.

In addition, the vacuum chamber 120 is connected to a gas supply tube 160 and a raw material supply tube 170.

The gas supply tube 160 is connected to a gas supply source 180 via a flow rate control valve 161. Opening and closing operation of the flow rate control valve 161 allows adjustment of the flow rate of a gas supplied to the vacuum chamber 120.

As an added gas supplied from the gas supply source 180, for example, there may be mentioned argon, helium, nitrogen, etc. More preferable is argon.

The raw material supply tube 170 is connected to a raw material container 190 for storing a raw material gas via a flow rate control valve 171. Under the raw material container 190, a heater 191 is disposed. When a raw material stored in the raw material container 190 is a liquid, the liquid material can be heated by the heater 191 to be vaporized and gasified.

The raw material gas is absorbed with a negative pressure of the vacuum chamber 120 and supplied thereto through the raw material supply tube 170. The flow rate of the raw material gas supplied to the vacuum chamber 120 is controlled by the opening and closing operation of the flow rate control valve 171.

Now, a description will be given of a method of forming the anode buffer layer 8 using the plasma polymerizing apparatus 100.

First, the TFT circuit substrate 20 having the anode 3 formed thereon in the previous process [2-B] is placed on the stage 140 in the vacuum chamber 120.

Next, a raw material gas is introduced into the raw material container 190.

After that, operation of the pump 110 reduces a pressure inside the vacuum chamber 120 down to a determined level.

The pressure thereinside is preferably equal to or less than approximately 1 Torr, and more preferably equal to or less than approximately 1×10⁻⁴ Torr.

Then, by the temperature adjustment mechanism of the stage 140, a temperature of the TFT circuit substrate 20 is adjusted so as to promote plasma polymerization of the raw material gas.

The temperature thereof is preferably equal to or higher than 25 degrees centigrade, and more preferably it ranges from approximately 25 to 100 degrees centigrade.

Next, according to needs, an oxygen gas is supplied from the gas supply tube 160 into the vacuum chamber 120.

Then, a usual oxygen plasma process is performed on a surface of the first bank 31. This process allows a functional group such as a hydroxyl group to be introduced onto the surface thereof. As a result, it can increase adhesiveness of the first bank 31 to the second bank 32 to be described later.

After the oxygen plasma process, the pressure inside the vacuum chamber 120 is reduced again to the determined level according to needs.

Next, an added gas from the gas supply tube 160 and the raw material gas from the raw material supply tube 170 are each supplied into the vacuum chamber 120.

Preferably, a flow rate of the added gas ranges from approximately 10 to 500 sccm.

Meanwhile, a flow rate of the raw material gas preferably ranges from approximately 1 to 100 sccm, and more preferably from approximately 30 to 70 sccm.

In addition, after supplying the raw material gas, the atmospheric pressure inside the vacuum chamber 120 preferably ranges from approximately 0.01 to 1 Torr, and more preferably from approximately 0.1 to 0.5 Torr.

Next, the high-frequency electric power supply 150 applies a high-frequency electric power to the electrode 130, whereby an argon plasma is generated inside the vacuum chamber 120. Then, electron collision excitation by the argon plasma activates the raw material gas. This causes polymerization near the surface of the TFT circuit substrate 20, resulting in formation of a coating film comprised of a polymeric substance.

Here, the used raw material gas contains a precursor (monomer) corresponding to a desired polysiloxane derivative.

The precursor changes into a polysiloxane derivative (polymer) due to the plasma polymerization. This consequently enables formation of a coating film of compact substance, which is made mostly of the polysiloxane derivative. Additionally, the polysiloxane derivative generated by the plasma polymerization changes into SiO₂ in a process to be described later. This can suppress occurrence of structural defects such as a void and the like.

Furthermore, the polysiloxane derivative has a structure mainly consisted of Si—O binding (siloxane binding), and also has a substituent binding to Si. The substituent changes into various substances, whereby physical properties of the polysiloxane derivative also change.

As the substituent, for example, there may be mentioned an alkyl group, an alkoxyl group, a halogen group, etc. A kind of them or a combination of two or more kinds of them may be used.

In addition, the polysiloxane derivative employed in the invention preferably includes a substituent from at least one of an alkyl group with carbon numbers of 1 to 8, an alkoxyl group with carbon numbers of 1 to 8 and a halogen group. The polysiloxane derivative including such a substituent has particularly high lyophobic properties. As a result, the polysiloxane derivative can prevent alteration and deterioration due to moisture absorption and attachment of impurities during the manufacturing processes.

In particular, it is preferable to use a substituent from the alkyl group with carbon numbers of 1 to 8, and more preferably a substituent from a methyl group. The polysiloxane derivative having such a substituent is relatively stable and easy to use.

In this case, methylpolysiloxane is an example of the polysiloxane derivative having a methyl group. Methlpolysiloxane is a polymer generated from an octamethyltrisiloxane (OMTS) precursor. Since the OMTS is particularly chemically stable and inexpensive, it is a preferred precursor to be used.

Next, a combination of photolithography and etching is used to remove the coating film formed on the bank 35.

[2-Cb] Then, ultraviolet light is irradiated onto the coating film produced in the process [2-Ca] to change the polysiloxane derivative in the coating film into SiO₂. As a result, the anode buffer layer 8 can be produced (Second Process), The irradiation of ultraviolet light onto the polysiloxane derivative breaks coupling hands of atoms in accordance with energy of the ultraviolet light. As a result, the binding of Si and each of the above substituents, in which the binding energy is smaller than the Si—O binding energy, is broken at a high ratio, whereby a new Si—O binding is formed. Due to the result, the polysiloxane derivative in the coating film gradually changes into SiO₂.

In view of the situation, it is preferable that the energy of the ultraviolet light be greater than the binding energy of Si and the substituent and be smaller than the Si—O binding energy. In this manner, while the Si—O binding is not substantially broken, the binding of Si and the substituent can selectively be broken. Consequently, the polysiloxane derivative can more effectively be changed into SiO₂, whereby the anode buffer layer 8 can be formed.

In addition, when the polysiloxane derivative changes into SiO₂, a thickness of the coating film reduces along with the change. One reason for this is that a gas constituted by separated substituents is discharged from the coating film. As a result, the film thickness gradually decreases in accordance with a ratio in which the polysiloxane derivative changes into SiO₂.

Furthermore, the irradiation of the ultraviolet light is preferably performed in an atmosphere substantially containing no oxygen. This can prevent absorption of ultraviolet light and ozone formation due to oxygen, thereby effectively changing the polysiloxane derivative into SiO₂. Consequently, it can more reliably protect SiO₂ generated by the ultraviolet-light irradiation from alteration and deterioration due to influence of vapor.

As the gas in the atmosphere, it is preferable to use a gas that does not absorb ultraviolet light, particularly, a gas whose molecule consists exclusively of sigma bonds, such as a nitrogen gas or a rare gas. Additionally, the atmosphere may be depressurized.

In the past, a film of SiO₂ has been formed by using a liquid phase process such as a sol-gel method, a physical vapor deposition method such as sputtering, a chemical vapor deposition method such as CVD, etc. These film-forming methods, however, require a depressurized atmosphere, thermal treatment at a high temperature and the like. Accordingly, it takes time to move on to the next process. Besides, there have been potential thermal negative effects on a TFT circuit or the like.

Therefore, in the present invention, immediately before the formation of a semiconductor layer, ultraviolet light is irradiated to change the polysiloxane derivative into SiO₂. This method allows processing under a normal pressure, and also can prevent the above-mentioned thermal effects, so that processing can be easily done. Moreover, it is unnecessary to conduct a troublesome task such as returning from a depressurized state to a normal-pressure state. Accordingly, there is an advantage that it does not take time to move on to the next stage of the process.

[2-D] Next, following the previous process [2-Cb], as shown in FIG. 3B, the positive-hole transporting layer 4 and then the light-emitting layer 5 are formed on each anode buffer layer 8 so as to laminate those layers in the sequential order (Third Process).

Here, as described above, the anode buffer layer 8 formed by the previous process [2-Cb] is made mostly of SiO₂.

In general, an SiO₂ surface has a high wettability and shows particularly a highly lyophilic property with respect to a polar solvent such as water. Accordingly, when exposed to an air atmosphere, the SiO₂ surface absorbs moisture in the air and causes alteration and deterioration, which interferes with transmittance of a carrier through the SiO₂ film. Additionally, attachment of impurities causes problems in injection of the carrier into a semiconductor layer from the SiO₂ film. Therefore, depending on the state of SiO₂, a time in which SiO₂ is exposed to the air atmosphere needs to be shortened as much as possible.

Furthermore, for example, when the anode buffer layer 8 made of SiO₂ having such properties is covered with the positive-hole transporting layer 4, it can be separated from the air, so that subsequent moisture absorption and attachment of impurities can be prevented.

On the other hand, the polysiloxane derivative formed by the previous process [2-Ca] is highly hydrophobic. Even when exposed to the air atmosphere, it is unlikely to cause alteration and deterioration associated with moisture absorption.

Therefore, preferably, the third process is performed immediately after the previous process [2-Cb]. In other words, formation of the positive-hole transporting layer 4 and the light-emitting layer 5 in the third process is preferably started as immediately as possible before alteration and deterioration due to moisture absorption occur on the anode buffer layer 8, after the polysiloxane derivative has changed into SiO₂ in the process [2-Cb].

The above-described manner can reduce the time in which moisture absorption and attachment of impurities can occur on the SiO₂ surface, thereby preventing alteration and deterioration of the anode buffer layer 8 and poor contact thereof with the semiconductor layer associated with those problems. Thus, for example, during the processes for manufacturing the display 10, when any of the processes needs to be stopped for long hours, it is preferable to avoid leaving SiO₂ exposed to the air after terminating the process [2-Cb]. That is to say, if it is after the process [2-Ca] has finished, even if exposed to the air atmosphere for relatively long hours, the possibility is small that alteration and deterioration occur in the characteristics and the like of the polysiloxane derivative. Accordingly, it is easy to conduct a long-hour cessation and the like during the processes.

Regarding the shortened time mentioned above, specifically, it is preferably within 5 minutes, and more preferably within 3 minutes. In such a short-time exposure, moisture absorption of the anode buffer layer 8, even in the air atmosphere, can be prevented without fail. This results in prevention of alteration and deterioration thereof.

The anode buffer layer 8 produced in the above manner is made of SiO₂ having less structural defaults. The SiO₂ is generated from the polysiloxane derivative of compact substance formed by plasma polymerization. Accordingly, hygroscopicity of the layer particularly decreases, and especially excellent positive-hole injection characteristics can be obtained. Additionally, the display 10 having the anode buffer layer 8 with such characteristics can have a high light-emitting efficiency.

[2-Da] First, the positive-hole transporting layer (semiconductor layer) 4 is disposed on each anode 3.

The positive-hole transporting layer 4 may be formed by a gas phase process such as vacuum deposition or a liquid phase process such as spin coating. The present embodiment uses a liquid phase process using an inkjet method (liquid droplet ejection method) to form the positive-hole transporting layer 4. Use of the inkjet method can make the positive-hole transporting layer 4 thinner and can produce a micro pixel. Moreover, a liquid material used for forming the positive-hole transporting layer 4 can selectively be supplied to the inside of the bank 35. Thus, the material can be used without any waste.

Specifically, the liquid material for the positive-hole transporting layer 4 is ejected from a head of an inkjet printer and supplied onto each anode 3. Then, after desolvation and separation from a dispersion medium, thermal treatment, if needed, is performed for a short time at a temperature of approximately 150 degrees centigrade.

The desolvation and separation from a dispersion medium may include a process for exposing a material to a depressurized atmosphere, thermal treatment (for example, in a temperature ranging from approximately 50 to 60 degrees centigrade), flowing of an inert gas such as nitrogen gas, etc. Furthermore, additional thermal treatment (for a short time at approximately 150 degrees centigrade) is conducted to remove a remaining solvent.

[2-Db] Next, the light-emitting layer (semiconductor layer) 5 is formed on each positive-hole transporting layer 4 (on a side opposite to a part where the anode 3 is formed on the TFT circuit substrate 20).

The light-emitting layer 5 can also be formed by a liquid phase process. Preferably, it is formed by a liquid phase process using the inkjet method (liquid droplet ejection method), similar to the case described above.

Additionally, when forming the light-emitting layers 5 for emitting lights of a plurality of colors, there is an advantage that the inkjet method facilitates separate pattern coloring with individual colors.

[2-E] Next, as shown in FIG. 3C, each common cathode 6 is formed on each light-emitting layer 5 and each bank 35, that is, so as to cover each light-emitting layer 5 and each bank 35 (Fourth Process).

The cathode 6 may be formed similarly to the formation of the gate electrode 243, for example.

In this embodiment, the cathode 6 is formed on entire surfaces of the light-emitting layer 5 and the bank 35. Thus, since no mask is required, it is suitable to use a gas phase process using vacuum deposition or the like for the formation thereof.

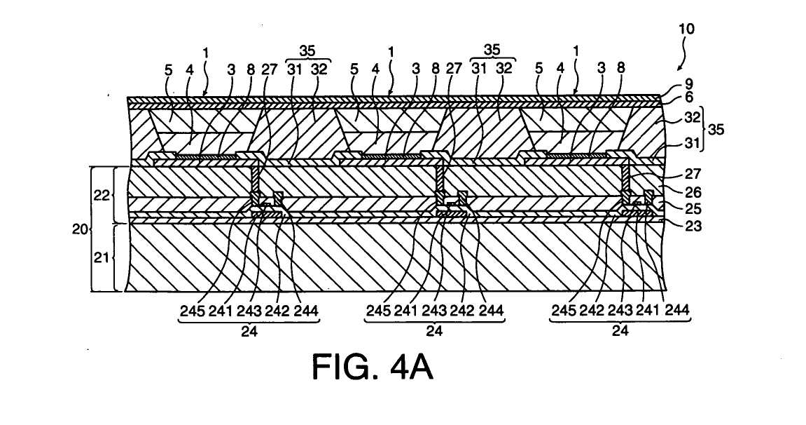

Through the processes described above, the organic EL element 1 is manufactured.

[3] Next, the upper substrate 9 is prepared, and as shown in FIG. 4A, the cathode 6 and the upper substrate 9 are bonded to each other so as to cover the cathode 6 with the upper substrate 9.

The cathode 6 and the upper substrate 9 can be bonded to each other by applying an epoxy adhesive therebetween, then drying the adhesive, etc.

The upper substrate 9 functions as a protective substrate for protecting the organic EL element 1. Disposition of the upper substrate 9 on the cathode 6 can prevent the organic EL element 1 from contacting with oxygen and moisture, or can reduce the possibility of contact therewith. Accordingly, such advantages can be obtained as improved reliability of the organic EL element 1, prevention of alteration and deterioration thereof, etc.

Through the processes described above, the display 10 can be manufactured.

### Second Embodiment

Next, descriptions will be given of an active matrix display applied as a light-emitting device according to a second embodiment of the invention, an organic EL element according to the second embodiment, which is included in the light-emitting device, and a manufacturing method thereof.

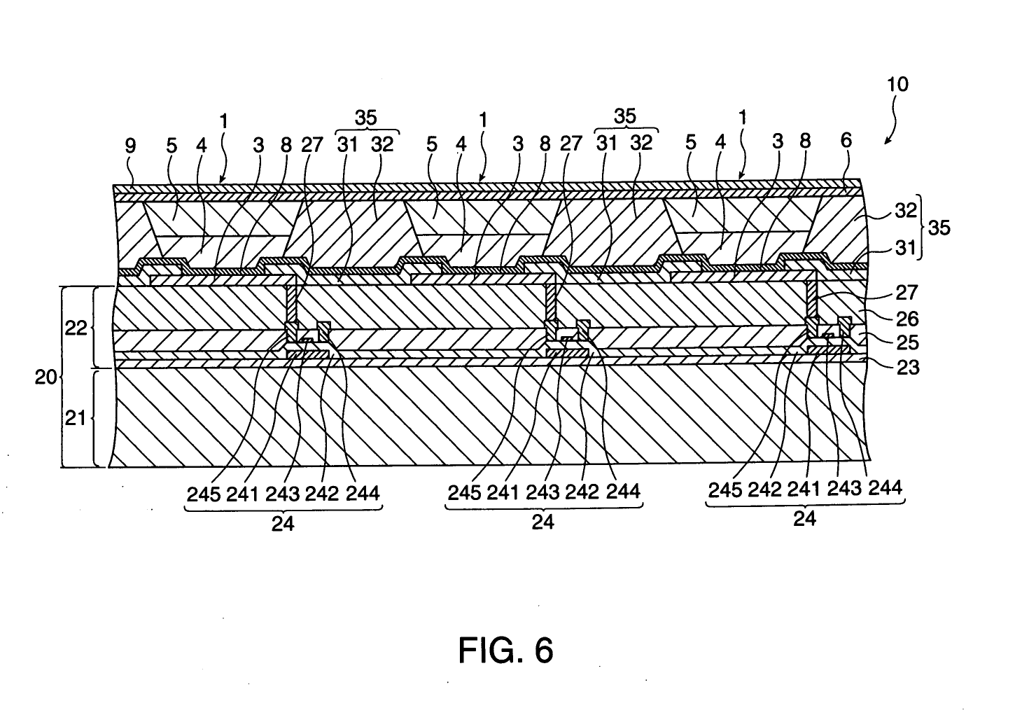

FIG. 6 is a longitudinal cross-sectional view showing the active matrix display according to the second embodiment. In the description below, upper and lower sides in FIG. 6 will be referred to as “upper” and “lower”.

In the second embodiment described below, differences from the first embodiment will mainly be discussed, and the description of the same parts will be omitted.

The display 10 employed in the second embodiment is the same as that in the first embodiment, except for a structural difference of the anode buffer layer 8.

Specifically, in this embodiment, as shown in FIG. 6, the anode buffer layer 8 is formed successively so as to cover the anode 3 and the first bank 31. Additionally, the second bank 32 is formed on the anode buffer layer 8.

The display 10 is manufactured in the process [2-C], before forming the second bank 32, after forming the first bank 31 in the process [2-B]. The manufacturing method does not require patterning process for the anode buffer layer 8. Therefore, the manufacturing processes can be simplified.

In this case, after forming a plasma-polymerized film so as to cover the exposed entire surfaces (top surfaces of the anode 3 and the first bank 31), it is preferable to selectively change a region to form the second bank 32 into SiO₂ before changing a part corresponding to the anode 3 into SiO₂. In this manner, since only the region changes into SiO₂ and shows a lyophilic property, the second bank 32 can be easily formed by a liquid-material supplying method such as an inkjet method, misting or the like. After this, the part corresponding to the anode 3 can be changed into SiO₂.

In addition, after formation of the plasma-polymerized film, ultraviolet light may be irradiated on an entire surface of the film. Consequently, the entire plasma-polymerized film changes into SiO₂ and shows a lyophilic property. Accordingly, the second bank 32 can be efficiently formed by a liquid-material supplying method having a higher productivity, such as spin coating, dip coating or the like, and subsequent patterning thereafter.

### Third Embodiment

Next, descriptions will be given of an active matrix display applied as a light-emitting device according to a third embodiment of the invention, an organic EL element applied as a light-emitting element according to the third embodiment thereof, which is included in the light-emitting device, and a manufacturing method thereof.

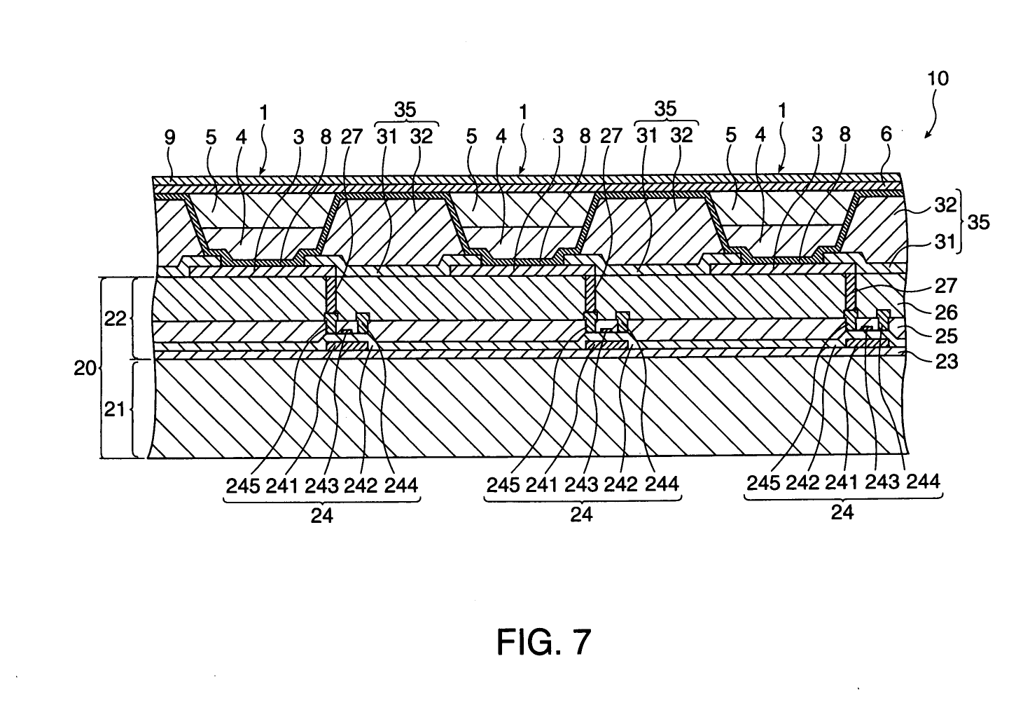

FIG. 7 is a longitudinal cross-sectional view showing the active matrix display according to the third embodiment. In the description below, upper and lower sides in FIG. 7 will be referred to as the “upper” and “lower”.

In the third embodiment below, differences from the first and second embodiments will mainly be discussed, and the description of the same parts will be omitted.

The display 10 employed in the third embodiment is the same as that in the first embodiment, except for the structural difference of the anode buffer layer 8.

Specifically, in this embodiment, as shown in FIG. 7, the anode buffer layer 8 is formed successively so as to cover the anode 3 and the bank 35 (first and second banks 31 and 32).

The display 10 can be manufactured by a simplified patterning process of forming the anode buffer layer 8 only on the anode 3 in the process [2-Ca]. Accordingly, the method can shorten the manufacturing processes.

In this case, preferably, after forming the plasma-polymerized film so as to cover the anode 3 and the bank 35, ultraviolet light is selectively irradiated on the anode 3 and an exposed part of the first bank 31. In this manner, since only the relevant region changes into SiO₂ and shows a lyophilic property, the positive-hole transporting layer 4 and the light-emitting layer 5 can easily be formed by a liquid-material supplying method such as an inkjet method, misting or the like.

Additionally, after formation of the plasma-polymerized film, ultraviolet light may be irradiated on an entire surface of the film. Then, the entire plasma-polymerized film changes into SiO₂ and shows a lyophilic property. Accordingly, using a liquid-material supplying method having a higher productive efficiency, such as spin coating, dip coating or the like, the display 10 can be manufactured more efficiently.

Furthermore, in the third embodiment, since the first and second banks 31 and 32 are both covered with the anode buffer layer 8, it saves the task of disposing them individually. Accordingly, in the process [2-B], for example, when forming the first bank 31, a pattern equivalent to the bank 35 may be formed. This arrangement can omit the second bank 35, resulting in further simplification of the manufacturing processes.

Electronic Apparatus

The display (light-emitting device according to the embodiments of the invention) 10 can be incorporated in various kinds of electronic apparatuses.

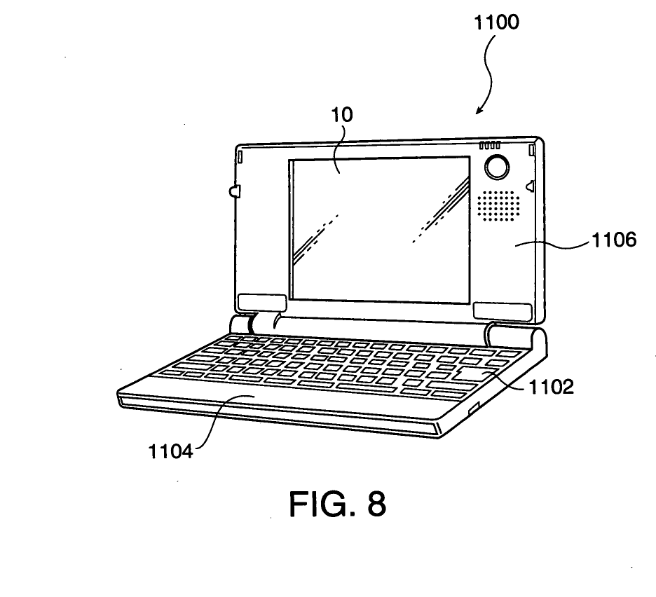

FIG. 8 is a perspective view showing a structure of a mobile (or notebook) personal computer applied as an example of an electronic apparatus according to the embodiments of the invention.

In this figure, a personal computer 1100 has a main body 1104 with a key board 1102 and a display unit 1106 with a display section. The display unit 1106 is supported rotatably with respect to the main body 1104 via a hinge structure.

In the personal computer 1100, the display section included in the display unit 1106 is constituted by the display 10 described above.

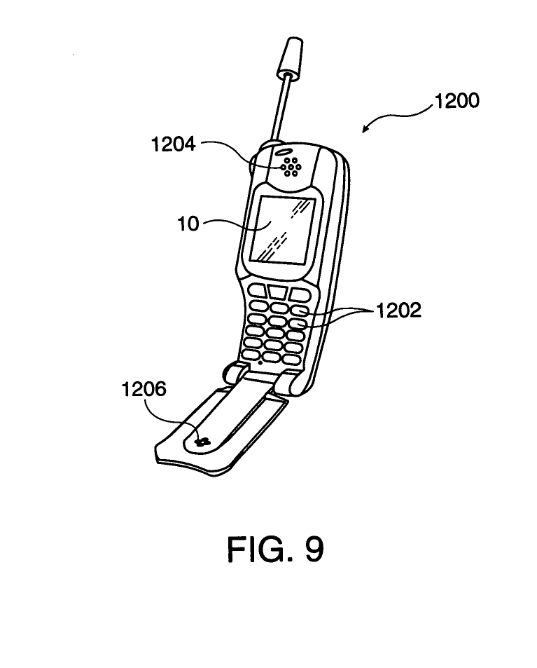

FIG. 9 is a perspective view showing a structure of a mobile phone (including PHS) applied as another example of the electronic apparatus according to the third embodiments thereof.

In this figure, a mobile phone 1200 has a plurality of operation buttons 1202, an earpiece 1204, a mouthpiece 1206, and a display section.

In the mobile phone 1200, the display section is constituted by the display described above.

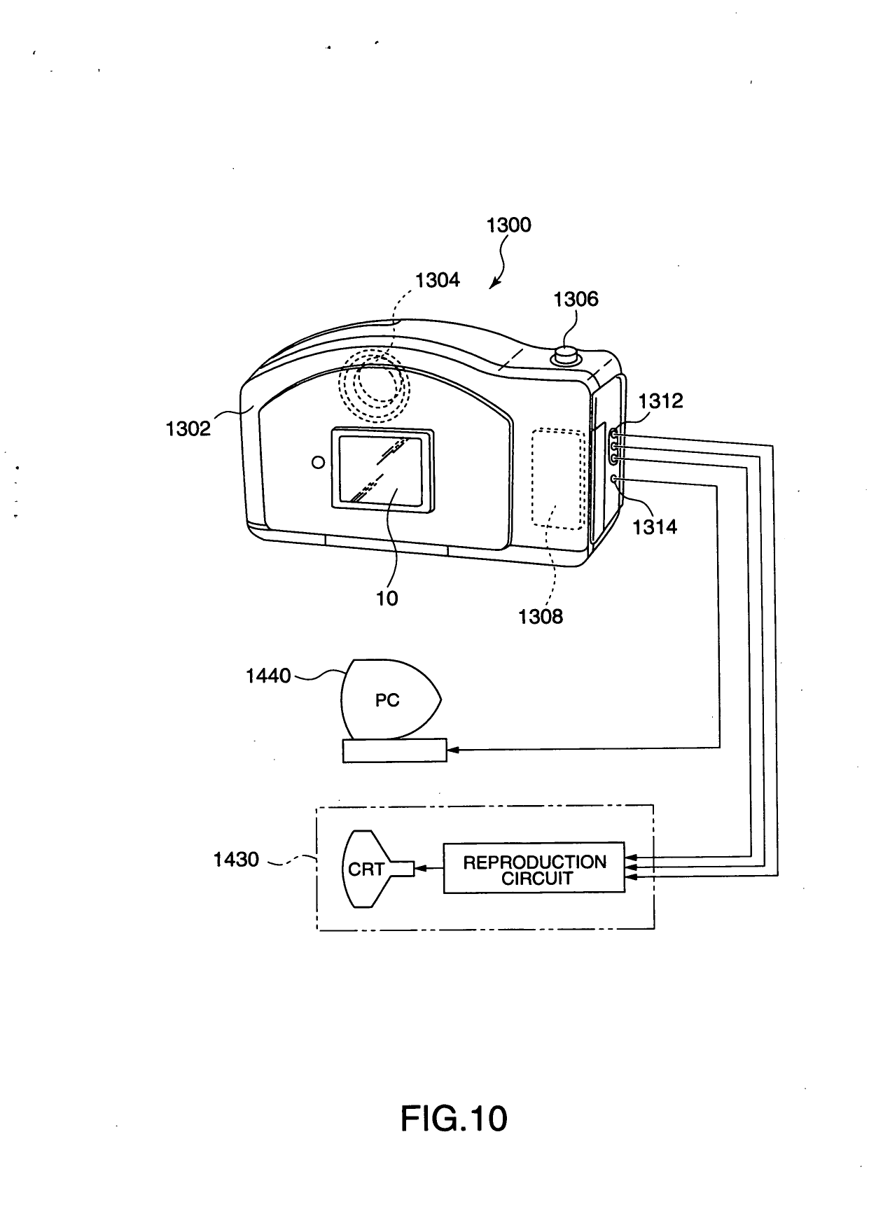

FIG. 10 is a perspective view showing a structure of a digital still camera applied as another example of the electronic apparatus according to the embodiment of the invention. In this figure, connections with external apparatuses are also simply shown.

Here, in an ordinary camera, a silver halide film is exposed to light of an optical image of an object, whereas a digital still camera 1300 generates an image-pickup signal (image signal) by photoelectric conversion of the optical image of an object using an image-pickup element such as a charge coupled device (CCD).

On a rear surface of a casing (body) 1302 in the digital still camera 1300, a display section is disposed to display images based on image-pickup signals from the CCD. Thus, the display section serves as a finder to display an electronic image of the object.

In the digital still camera 1300, the display section is constituted by the above-described display 10.

The casing has a circuit substrate 1308 disposed therein. The circuit substrate 1308 is provided with a memory capable of storing (memorizing) image-pickup signals.

In addition, a light-receiving unit 1304 including an optical lens (imaging optical system), CCD, etc., is disposed on a front surface (a back surface in a structure shown in the figure) of the casing 1302.

When an individual who takes a photo confirms the image of an object displayed on the display section and then pushes down a shutter button 1306, an image signal of the CCD at the point in time is transferred to the memory of the circuit substrate 1308 to be stored therein.

In the digital still camera 1300, a video signal output terminal 1312 and an input-output terminal 1314 used for data communications are disposed on a side surface of the casing 1302. Then, as shown in the figure, the video signal output terminal 1312 is connected to a television monitor 1430, and the input-output terminal 1314 for data communications is connected to a personal computer 1440, when needed, respectively. Furthermore, with a predetermined operation, the image-pickup signal stored in the memory of the circuit substrate 1308 is output to the television monitor 1430 or the personal computer 1440.

Other than the personal computer (mobile personal computer) shown in FIG. 8, the mobile phone shown in FIG. 9 and the digital still camera shown in FIG. 10, the electronic apparatus according to the embodiments of the invention may be applied to, for example, a television set, a video camera, a view-finder type or monitor direct-view-type video tape recorder, a laptop personal computer, a car navigation device, a pager, an electronic organizer (with communications functions), an electronic dictionary, an electronic calculator, an electronic game device, a word processor, a work station, a video phone, a security television monitor, an electronic binocular, a POS terminal, a device equipped with a touch panel (e.g. a cash dispenser in banking facilities, an automatic ticket vending machine), a medical device (e.g. an electronic thermometer, an electronic manometer, a glucosemeter, an electrocardiographic equipment, ultrasonic diagnostic equipment, an endoscopic display), a fish detector, various kinds of measuring equipment, gauging instruments (e.g. instruments of cars, airplanes and ships), a flight simulator, other kinds of monitors, a projection display apparatus such as a projector, etc. The electronic apparatus according to the embodiments of the invention is not limited to those having a display function, and any apparatus with a light-emitting function such as an optical source is applicable.

As described above, the exemplary embodiments of the invention have been explained with reference to the drawings. The invention, however, is not limited to those embodiments.

For example, the light-emitting element manufacturing method according to the embodiments of the invention may include additional one or more processes for any optional advantage.

### SPECIFIC EXAMPLES

Hereinafter, specific examples according to the embodiments of the invention will be described.

1. Manufacturing of Samples

In each of specific and referential examples below, 10 samples were manufactured.

### Example 1A

In a method as shown below, an anode buffer layer was formed to manufacture each sample.

[1a] First, a transparent glass substrate having a mean thickness of 5 mm was prepared and stored in the plasma polymerizing apparatus shown in FIG. 5.

[2a] Next, pressure inside the vacuum chamber of the plasma polymerizing apparatus was reduced to a level of 9×10⁻⁵ Torr. After this, while introducing an oxygen gas into the vacuum chamber, oxygen plasma treatment was performed under the following conditions.

Atmospheric pressure: 0.2 Torr

Flow rate of oxygen gas: 100 sccm

Plasma output: 100 W

Frequency of high-frequency electric power: 13.56 MHz

Treatment time: 1 minute

[3a] Next, again, after reducing the pressure to the level of 9×10⁻⁵ Torr, an argon gas (added gas) and an octamethyltrisiloxane (monomer) gas were introduced in the vacuum chamber, and then, plasma polymerization of octamethyltrisiloxane (OMTS) was conducted under the following conditions. As a result, a plasma-polymerized film (coating film) formed of a polysiloxane derivative was produced. In this case, the time for plasma polymerization treatment was set in such a manner that the plasma-polymerized film could have a mean thickness of 40 nm.

Atmospheric pressure: 0.2 Torr

Flow rate of argon gas: 10 sccm

Flow rate of OMTS gas: 50 sccm

Plasma output: 100 W

Frequency of high-frequency electric power: 13.56 MHz

Treatment time: 6 minutes 40 seconds

Film formation velocity: 6 nm/min

[4a] Next, ultraviolet light was irradiated on the produced plasma-polymerized film under the following conditions. As a result, the polysiloxane derivative in the plasma-polymerized film was changed into SiO₂, whereby the anode buffer layer was produced.

Wavelength of ultraviolet light: 365 nm

Luminance of ultraviolet light: 10 mW/cm²

Time of ultraviolet irradiation: 1 minute

Atmosphere under ultraviolet irradiation: air atmosphere

### Example 2A

Samples were manufactured in a similar manner to Example 1A, except that the time of ultraviolet irradiation was 10 minutes.

### Example 3A

Two kinds of optical sources for emitting ultraviolet light were prepared, and then ultraviolet lights having wavelengths of 254 nm and 184 nm were simultaneously irradiated. Except for those conditions, samples were manufactured in a similar manner to Example 1A.

### Examples 4A to 7A

Each sample was manufactured in a similar manner to Example 3A, except that the time of ultraviolet irradiation was set to be 10 minutes, 20 minutes, 40 minutes and 120 minutes, respectively.

### Example 5A

Samples were manufactured in a similar manner to Example 1A, except that the wavelength of ultraviolet light was set to be 172 nm and the atmosphere under irradiation thereof was nitrogen.

In this case, the nitrogen atmosphere was of dried nitrogen containing substantially no vapor.

### Examples 9A to 11A

Each sample was manufactured in a similar manner to Example 8A, except that the time of ultraviolet irradiation was set to be 10 minutes, 20 minutes and 40 minutes, respectively.

### Referential Example A

Samples were manufactured in a similar manner to Example 1A, except that the process [4a] was omitted and the plasma-polymerized film was formed as the anode buffer layer.

2. Evaluation of Samples

2-1. Measurement and Evaluation of an Xylene Contact Angle

In each of the samples manufactured in Examples 1A to 11A and Referential Example A, a contact angle of xylene was measured.

In this case, measurement of the contact angle was conducted based on a method stated in the “Test Method for Surface Wettability of Glass Substrate” (JIS R 3257).

Then, using droplets of xylene, a sessile drop method was performed to measure an angle (contact angle) formed by a rounded surface of the droplet in contact with a sample surface.

2-2. Evaluation of Changes in Thickness of Plasma-Polymerized Film

In the samples manufactured in Examples 1A to 11A and Referential Example A, volume changes in thickness of the plasma-polymerized film after ultraviolet irradiation were measured.

Table 1 shows evaluation results obtained in 2-1 and 2-2.

TABLE 1

| | | | | EVALUATION RESULTS | |
|---|---|---|---|---|---|
| | UV-IRRADIATION CONDITIONS | | | XYLENE | FILM |
| | WAVELENGTH | IRRADIATION | ATMOSPHERIC | CONTACT | THICKNESS |
| | [nm] | TIME [min] | COMPOSITION | ANGLE [°] | CHANGE [nm] |
| EX. 1A | 665 | 1 | Air | 20 | −1 |
| 2A | 365 | 10 | Air | 18 | −2 |
| 3A | 254 + 184 | 1 | Air | 4 | −1 |
| 4A | 254 + 184 | 10 | Air | 5 | −1 |
| 5A | 254 + 184 | 20 | Air | 7 | −4 |
| 6A | 254 + 184 | 40 | Air | 6 | −6 |
| 7A | 254 + 184 | 120 | Air | 6 | −9 |
| 8A | 172 | 1 | Nitrogen | 5 | −1 |
| 9A | 172 | 10 | Nitrogen | 4 | −7 |
| 10A | 172 | 20 | Nitrogen | 3 | −9 |
| 11A | 172 | 40 | Nitrogen | 3 | −10 |
| REF. A | — | — | — | 32 | 0 |

Note:
Table abbreviates Specific Example as EX. and Referential Example as REF.

As clear in Table 1, it can be seen that as energy of the ultraviolet light becomes higher (the wavelength becomes shorter), the contact angle of xylene with respect to the sample surface becomes smaller. This indicates that the higher the energy of ultraviolet light, the higher the ratio of SiO₂ on the sample surface. In other words, as described above, since SiO₂ has wettability with respect to liquids in general, it shows wettability with respect to xylene as well, and therefore the xylene contact angle seems to be small.

In Examples 8A to 11A using the wavelength of 172 nm, it is particularly obvious that the polysiloxane derivative changed into SiO₂ even when ultraviolet irradiation was performed for a short time of 1 minute.

Those results suggest that when the polysiloxane derivative on the sample surface changes into SiO₂, changing efficiency thereof varies with the energy of the ultraviolet light.

On the other hand, it can be found that as the time of ultraviolet irradiation became longer under the same level of energy, the thickness of the plasma-polymerized film (anode buffer layer) decreased.

The reason for this is assumed to be that, in the process during which the changing of the polysiloxane derivative into SiO₂ due to the ultraviolet irradiation proceeds from the surface of the plasma-polymerized film to the entire film, various substituents and the like become gaseous and are discharged from the coating film, whereby the thickness of the film decreases.

Also in this case, when ultraviolet light with the wavelength of 172 nm was irradiated for approximately 10 minutes, it is obvious that the thickness of the film sufficiently decreased and changing of the polysiloxane derivative into SiO₂ was performed without fail.

The evaluation results clarify that it is preferable to use the ultraviolet light with a shorter wavelength in order to change the polysiloxane derivative into SiO₂, and in the examples, preferable is the ultraviolet light with the shortest wavelength of 172 nm among all those evaluated.

3. Manufacturing of Organic EL Devices

Based on the evaluation results of the samples above, in each of the following specific examples and a comparative example, 10 organic EL devices (light-emitting devices) were manufactured.

### Example 1B

[1b] First, a transparent glass substrate having a mean thickness of 5 mm was prepared, and a circuit section was formed thereon, as described above.

[2b] Next, on the circuit section, an ITO film having a mean thickness of 150 nm was formed by sputtering, and then patterning was performed to produce an anode.

[3b] Then, after forming a film of SiO₂ having a mean thickness of 150 nm by sputtering so as to cover an edge of each anode, patterning was performed to form a first bank.

[4b] Next, after forming a coating film of fluororesin having a mean thickness of 1.5 μm on the first bank, patterning was performed to form a second bank.

[5b] Next, the glass substrate having the second bank formed thereon was stored in the plasma polymerizing apparatus shown in FIG. 5.

Then, after depressurization to the level of 9×10⁻⁵ Torr, while introducing oxygen gas in the vacuum chamber, oxygen plasma treatment was performed under the following conditions.

Atmospheric pressure: 0.2 Torr

Flow rate of oxygen gas: 100 sccm

Plasma output: 100 W

Frequency of high-frequency electric power: 13.56 MHz

Treatment time: 1 minute

[6b] Next, again, after depressurization to the level of 9×10⁻⁵ Torr, an argon gas (added gas) and an octamethyltrisiloxane (polysiloxane precursor) gas were introduced in the vacuum chamber, and then, plasma polymerization of octamethyltrisiloxane (OMTS) was conducted under the following conditions. As a result, a plasma-polymerized film (coating film) formed of a polysiloxane derivative was produced. Additionally, an unnecessary part of the plasma-polymerized film was removed. Here, given the reduction in film thickness due to the ultraviolet irradiation, the time for plasma polymerization treatment was set in such a manner that the anode buffer layer produced in the next process could have a mean thickness of 3 nm.

Atmospheric pressure: 0.2 Torr

Flow rate of argon gas: 10 sccm

Flow rate of OMTS gas: 50 sccm

Plasma output: 100 W

Frequency of high-frequency electric power: 13.56 MHz

Treatment time: 70 seconds

Film formation velocity: 6 nm/min

[7b] Next, ultraviolet light was irradiated on the produced plasma-polymerized film under the following conditions. As a result, the polysiloxane derivative in the plasma-polymerized film changed into SiO₂, whereby the anode buffer layer was produced.

Wavelength of ultraviolet light: 172 nm

Luminance of ultraviolet light: 10 mW/cm²

Time of ultraviolet irradiation: 20 minutes

Atmosphere under ultraviolet irradiation: air atmosphere

[8b] Next, 3 minutes after the process [7b], a mixed solution of poly(dioctylfluoren) and F8BT (a blend of poly dioctylfluorene-co-benzothiadiazole) was supplied on the anode buffer layer inside the bank by an inkjet method to form a light-emitting layer having a mean thickness of 50 nm.

[9b] Next, vacuum deposition was used to produce a Ca film having a mean thickness of 20 nm and an Al film having a mean thickness of 200 nm, whereby a cathode was formed.

[10b] Then, a polyimide substrate having a mean thickness of 1 mm was bonded onto the cathode by using an epoxy adhesive, whereby an organic EL device was manufactured.

### Example 2B

Organic EL devices were manufactured in a manner similar to Example 1B, except that the atmosphere under ultraviolet irradiation was a nitrogen atmosphere and the irradiation time was 1 minute.

Here, the nitrogen atmosphere was of dried nitrogen substantially containing no vapor.

### Example 3B

Organic EL devices were manufactured in a similar manner to Example 2B, except that the time of ultraviolet irradiation was 20 minutes.

### Example 4B

Organic EL devices were manufactured in a similar manner to Example 3B, except that the oxygen plasma treatment in the process [5b] was omitted.

### Example 5B

Organic EL devices were manufactured in a similar manner to Example 3B, except that the time of plasma polymerization treatment was set in such a manner that the anode buffer layer could have a mean thickness of 12 nm.

### Example 6B

Organic EL devices were manufactured in a similar manner to Example 3B, except that the process [8b] was started 5 minutes after the process [7b].

### Example 7B

Organic EL devices were manufactured in a similar manner to Example 3B, except that the process [8b] was started 10 minutes after the process [7b].

### Referential Example B

Organic EL devices were manufactured in a similar manner to Example 3B, except that instead of the processes [5b] to [7b], sputtering was performed to form a film of SiO₂ to produce the anode buffer layer.

Here, the sputtering condition was set in such a manner that the anode buffer layer could have a mean thickness of 3 nm.

4. Evaluation of Organic EL Devices

4-1. Luminance—Evaluation of Voltage Characteristics of Organic EL Devices

First, in the organic EL devices manufactured in Specific Examples 1B to 7B and Comparative Example B, a DC voltage was applied between the anode and cathode to measure luminance changes due to a gradual voltage increase (luminance—voltage characteristics). Then, luminance of each organic EL device at a predetermined voltage was measured as a relative luminance with respect to that obtained in Example 3B defined as 100.

Next, those relative luminance values were evaluated based on the following criteria.

A: relative luminance 90 or over

B: relative luminance 70 or over and less than 90

C: relative luminance 50 or over and less than 70

D: relative luminance less than 50

4-2. Evaluation of Lifetime of an Organic EL Device

First, in the organic EL device manufactured in each of the Specific Examples 1B to 7B and Referential Example B, a DC voltage was applied between the anode and cathode. In this case, levels of voltage and current were determined in such a manner that each organic EL device could have a predetermined luminance, and luminance changes over a certain period of time under the conditions were measured. Additionally, time taken until the light-emitting luminance decayed to 50% of an initial state (half-lifetime) was obtained. Here, the obtained half-lifetime was a relative half-lifetime with respect to that in Example 3B defined as 100.

Next, those relative half-lifetime values were evaluated based on the following criteria.

A: relative half-lifetime 90 or over

B: relative half-lifetime 70 or over and less than 90

C: relative half-lifetime 50 or over and less than 70

D: relative half-lifetime less than 60

Table 2 shows evaluation results obtained in 4-1 and 4-2.

TABLE 2

| | MANUFACTURING CONDITIONS | | | | | | | |
|---|---|---|---|---|---|---|---|---|
| | UV-IRRAD1ATION (UV-IR) | | | | AIR- | FILM | EVALUATION | |
| | CONDITIONS | | | OXYGEN | EXPOSURE | THICKNESS OF | RESULTS | |
| | WAVELENGTH | | ATMOSPHERIC | PLASMA | TIME AFTER | ANODE BUFFER | REL | REL. |
| | [nm] | IR-TIME[min] | COMP. | TREATMENT | UV-IR [min] | LAYER [nm] | LUMINANCE | LIFETIME |
| EX. 1B | 172 | 20 | Air | Done | 3 | 3 | C | C |
| 2B | 172 | 1 | Nitro. | Done | 3 | 3 | B | A-B |
| 3B | 172 | 20 | Nitro. | Done | 3 | 3 | A | A |
| 4B | 172 | 20 | Nitro. | None | 3 | 3 | B | C |
| 5B | 172 | 20 | Nitro. | Done | 3 | 12 | C | C |
| 6B | 172 | 20 | Nitro. | Done | 5 | 3 | A-B | A |
| 7B | 172 | 20 | Nitro. | Done | 10 | 3 | B-C | B |
| CMP. B | — | — | — | Done | — | 3 | D | D |

Note:
Table abbreviates EXAMPLE as EX., COMPARATIVE EXAMPLE as CMP., COMPOSITION as COMP., and RELATIVE. as REL.

As seen clearly in the evaluation results of the luminance-voltage characteristics shown in Table 2, it was confirmed that all the organic EL devices in Examples 1B to 7B had excellent light-emitting efficiency and a high level of luminance when compared at the predetermined voltage. In particular, those in the Example 3B showed the highest luminance level.

On the other hand, the organic EL devices in Comparative Example B showed inferior light-emitting efficiency with lower luminance level. This seems to be due to that the ultrathin film of SiO₂ formed by sputtering had less coatability, less flatness and less uniformity than the anode buffer layer in each specific example, and was inferior in positive-hole injection characteristics thereto.

In addition, the half-lifetime evaluation results in Table 2 show that all the organic EL devices in Examples 1B to 7B had a long half lifetime and excellent durability. In this case also, the organic EL device in Example 3B had a particularly long lifetime, namely, it showed a significant durability.

In contrast, Comparative Example B had a lifetime equal to or less than half of that of Example 3B, which was insufficient as a practical lifetime.

What is claimed is:

1. A method of manufacturing a light-emitting element, comprising:
forming a coating film on an anode by polymerizing a plurality of monomers, the coating film including a polysiloxane derivative;
forming an anode buffer layer by irradiating the coating film with an ultraviolet light, the polysiloxane derivative in the coating film being changed to a silicon dioxide by the irradiating with the ultraviolet light;
forming a semiconductor layer having at least a light-emitting layer on the anode buffer layer; and
forming a cathode on the semiconductor layer.

2. The method of manufacturing a light-emitting element according to claim 1, wherein the polysiloxane derivative includes a substituent from at least one of an alkyl group with carbon numbers of 1 to 8, an alkoxyl group with carbon numbers of 1 to 8 and a halogen group.

3. The method of manufacturing a light-emitting element according to claim 1, wherein an energy of the irradiated ultraviolet light is greater than a binding energy between silicon (Si) and the substituent, and is smaller than a silicon-oxygen (Si—O) binding energy.

4. The method of manufacturing a light-emitting element according to claim 1, wherein the ultraviolet light is irradiated in an atmosphere containing no oxygen.

5. The method of manufacturing a light-emitting element according to claim 1, wherein the forming a semiconductor layer is started before deterioration due to moisture absorption or attachment of impurities occurs on the anode buffer layer after the forming an anode buffer layer.

6. The method of manufacturing a light-emitting element according to claim 5, wherein the forming a semiconductor layer is started in an air atmosphere within 5 minutes after the forming an anode buffer layer.

7. The method of manufacturing a light-emitting element according to claim 1, wherein the anode buffer layer is formed so as to have a mean thickness of equal to or less than 10 nm.
